(19) United States
(12) Patent Application Publication
(10) Pub. No.: US 2009/0072246 A1
(43) Pub. Date: Mar. 19, 2009

(54) Diode and memory device comprising the same

(75) Inventors: Stefanovich Genrikh, Suwon-si (KR); Bo-soo Kang, Seoul (KR); Young-soo Park, Yongin-si (KR); Xianyu Wenxu, Suwon-si (KR); Myoung-Jae Lee, Suwon-si (KR); Seung-eon Ahn, Suwon-si (KR); Chang-bum Lee, Seoul (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/076,308

(22) Filed: Mar. 17, 2008

(30) Foreign Application Priority Data
Sep. 18, 2007 (KR) 10-2007-0094898

(51) Int. Cl. H01L 33/00

(52) U.S. Cl. 257/79; 257/E33.001

(57) ABSTRACT

Provided are a diode and a memory device comprising the diode. The diode includes a p-type semiconductor layer and an n-type semiconductor layer, wherein at least one of the p-type semiconductor layer and the n-type semiconductor layer comprises a resistance changing material whose resistance is changed according to a voltage applied to the resistance changing material.

### CROSS-REFERENCE TO RELATED PATENT APPLICATION

This application claims the benefit of Korean Patent Application No. 10-2007-0094898, filed on Sep. 18, 2007, in the Korean Intellectual Property Office, the disclosure of which is incorporated herein in its entirety by reference.

### BACKGROUND OF THE INVENTION

1. Field of the Invention

The present invention relates to a semiconductor device, and more particularly, to a diode and a memory device comprising the same.

2. Description of the Related Art

Unit cells of a memory device each include a storage node and a switching device connected to the storage node. The switching device controls the access of signals to the storage node.

Switching devices that are generally used include PN diodes and metal-oxide-semiconductor field effect transistors (MOSFETs). The PN diodes can be applied to a multi-stack memory device such as a multi-layer cross point resistive random access memory device.

In order to increase the integration density of a memory device, the PN diodes may have a high forward current density. In the case of the PN diodes having a low forward current density, a small size PN diode can hardly ensure a sufficiently large forward current density for setting or resetting of a memory device. It is known that a PN diode has a forward current density of a few thousand A/cm², however, such PN diode can hardly increase the integration density of a memory device.

### SUMMARY OF THE INVENTION

To address the above and/or other problems, the present invention provides a diode having a high forward current density.

The present invention also provides a memory device comprising the diode having a high forward current density.

According to an aspect of the present invention, there is provided a diode comprising a p-type semiconductor layer and an n-type semiconductor layer, wherein at least one of the p-type semiconductor layer and the n-type semiconductor layer comprises a resistance changing material whose resistance is changed according to a voltage applied to the resistance changing material.

According to another aspect of the present invention, there is provided a memory device comprising: a diode; and a storage node connected to the diode, wherein the diode comprises a p-type semiconductor layer and an n-type semiconductor layer contacted with the p-type semiconductor layer, and at least one of the p-type semiconductor layer and the n-type semiconductor layer comprises a resistance changing material whose resistance is changed according to a voltage applied to the resistance changing material.

The resistance changing material may have a metal-insulator transition (MIT) characteristic.

The resistance changing material may be an oxide or a sulfide.

The oxide may comprise at least one selected from the group consisting of a vanadium oxide, a niobium oxide, and a titanium oxide.

The sulfide may be a vanadium sulfide.

The storage node may comprise a data storage layer formed of one of a resistance changing layer, a phase changing layer, a ferroelectric layer, and a magnetic layer.

The storage node may comprise a stack in which a lower electrode, a data storage layer and an upper electrode are sequentially stacked.

The data storage layer may be a resistance changing layer, and the memory device may be a multi-layer cross point resistive random access memory device having a 1D(diode)-1R(resistance) cell structure.

### BRIEF DESCRIPTION OF THE DRAWINGS

The above and other features and advantages of the present invention will become more apparent by describing in detail exemplary embodiments thereof with reference to the attached drawings in which:

FIG. 1 is a cross-sectional view of a diode according to an embodiment of the present invention;

FIG. 2 is a graph showing a voltage-current characteristic of an n-type semiconductor layer that is included in the diode of FIG. 1, according to an embodiment of the present invention;

FIGS. 3A and 3B are graphs showing voltage-current characteristics of first and second samples of a diode, according to embodiments of the present invention;

FIGS. 4 and 5 are cross-sectional views of memory devices comprising a diode according to embodiments of the present invention; and

FIG. 6 is a perspective view of a multi-layer cross point resistive random access memory device comprising diodes, according to an embodiment of the present invention.

### DETAILED DESCRIPTION OF THE INVENTION

The present invention will now be described more fully with reference to the accompanying drawings in which exemplary embodiments of the invention are shown. In the drawings, the thicknesses of layers and regions are exaggerated for clarity, and like reference numerals refer to the like elements.

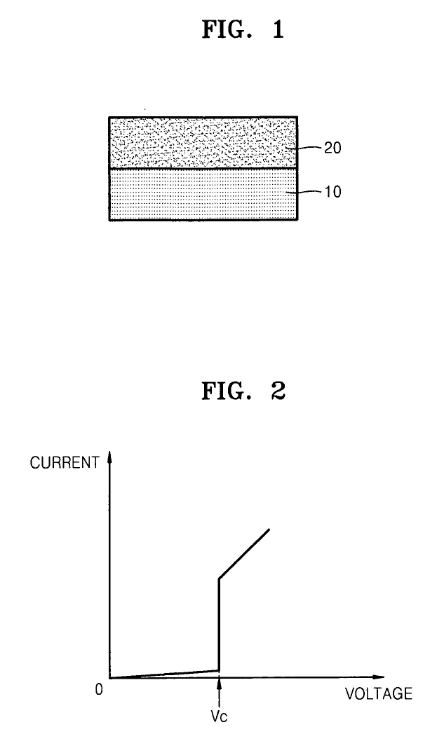

FIG. 1 is a cross-sectional view of a diode according to an embodiment of the present invention.

Referring to FIG. 1, a p-type semiconductor layer 10 is formed on an n-type semiconductor layer 20. The p-type semiconductor layer 10 and the n-type semiconductor layer 20 contact with each other. At least one of the p-type semiconductor layer 10 and the n-type semiconductor layer 20 has a resistance changing characteristic. For example, the n-type semiconductor layer 20 can be a resistance changing layer and may have a voltage-current characteristic as shown in FIG. 2.

Referring to FIG. 2, if a voltage greater than a predetermined voltage (a critical voltage) Vc is applied to the n-type semiconductor layer 20, the resistance of the n-type semiconductor layer 20 is rapidly reduced. That is, if a voltage lower than the critical voltage Vc is applied to the n-type semiconductor layer 20, the n-type semiconductor layer 20 has a high resistance like an insulator; however, if a voltage greater than the critical voltage Vc is applied to the n-type semiconductor layer 20, the n-type semiconductor layer 20 has a low resistance like a metal. Such resistance changing characteristic is referred to a metal-insulator transition (MIT) characteristic.

A resistance-changing material having the MIT characteristic can be an oxide or a sulfide. For example, the oxide can be at least one of a vanadium oxide, a niobium oxide, and a titanium oxide, and the sulfide can be a vanadium sulfide.

One of the p-type semiconductor layer 10 and the n-type semiconductor layer 20 may not have the MIT characteristic. For example, the p-type semiconductor layer 10 can be a silicon layer into which a p-type dopant is doped, or a p-type oxide such as an NiO layer or a CuO layer, and may not have the MIT characteristic. However, in another embodiment of the present invention, instead of the n-type semiconductor layer 20, the p-type semiconductor layer 10 may have the MIT characteristic, or both the p-type semiconductor layer 10 and the n-type semiconductor layer 20 may have the MIT characteristic.

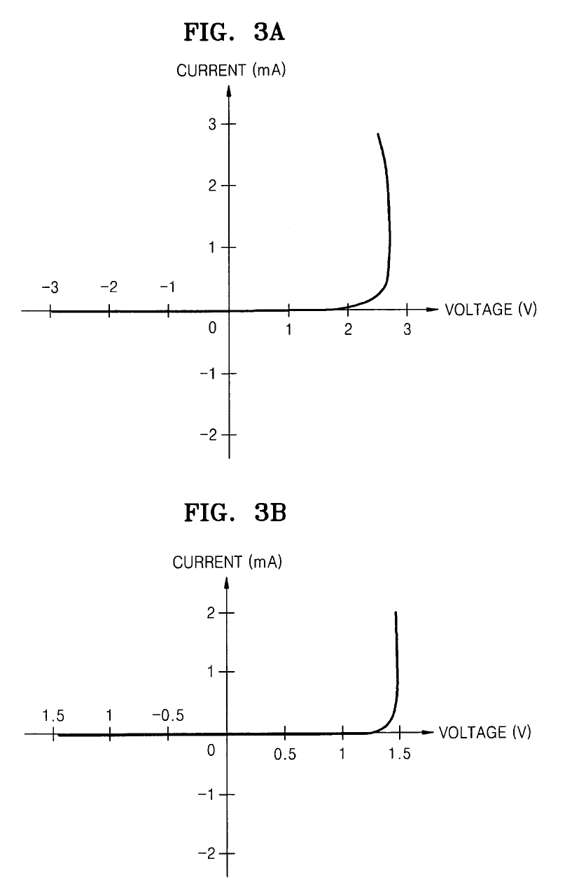

FIGS. 3A and 3B are graphs of voltage-current characteristics of first and second samples of a diode, according to embodiments of the present invention. FIG. 3A shows the voltage-current characteristic of the first sample that has the structure of the diode of FIG. 1 and in which a p-type silicon layer is used as the p-type semiconductor layer 10, and a VOx layer (where, x is a real number that satisfies 1.85<x<2.16) is used as the n-type semiconductor layer 20. FIG. 3B shows the voltage-current characteristic of the second sample that has the same structure as the first sample; however a VOy layer (where, y is a real number that satisfies 2.34<y<2.51) is used instead of the VOx layer.

Referring to FIGS. 3A and 3B, it is seen that currents rapidly increase at a predetermined voltage, and the current does not flow to a predetermined negative voltage. This proves that the diode, according to the embodiments of the present invention, has a rectification characteristic.

The results of FIGS. 3A and 3B are obtained by applying a voltage between the p-type semiconductor layer 10 (that is, the p-type silicon layer of the first and second samples) and the n-type semiconductor layer 20 (that is, the VOx and VOy layers respectively of the first and second samples) using an Au probe. Since a contact area between the p-type semiconductor layer 10 and the n-type semiconductor layer 20 and the Au probe is approximately 1 μm², from FIGS. 3A and 3B, it can be seen that the forward current density of the diode according to an embodiment of the present invention is approximately 2×10⁵˜3×10⁵ A/cm² which is about 100 times greater than the forward current density (a few thousand A/cm²) of a conventional PN diode. The reason why the diode according to the present embodiments has a larger forward current density is that at least one of the p-type semiconductor layer 10 and the n-type semiconductor layer 20 has a resistance changing characteristic. That is, the resistance of at least one of the p-type semiconductor layer 10 and the n-type semiconductor layer 20, for example, the n-type semiconductor layer 20 is rapidly reduced at a predetermined voltage, and thus, the forward current of the diode can be increased to a high value. Accordingly, although a diode according to the present embodiment has a small size, the diode can ensure a sufficiently large forward current density required for device operation. If the diode according to the present embodiment is used as a switching device, a memory device having a high integration density and a high operation characteristic can be realized.

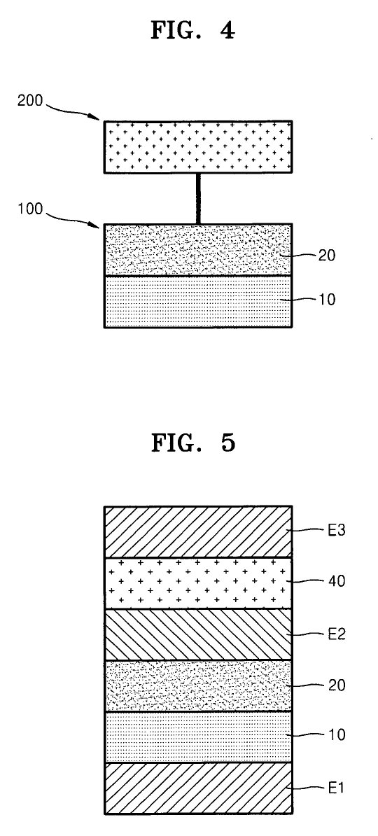

FIGS. 4 and 5 are cross-sectional views of a memory device comprising a diode according to embodiments of the present invention.

Referring to FIG. 4, a data storage unit 200 is connected to the diode 100 that includes the p-type semiconductor layer 10 and the n-type semiconductor layer 20 formed on the p-type semiconductor layer 10. The diode 100 may be the diode of FIG. 1. The data storage unit 200 can be a resistance changing layer like an NiₓO_{y} layer, or can be a phase changing layer, a ferroelectric layer, or a magnetic layer. The data storage unit 200 of FIG. 4 has a single layer structure, however, the present invention is not limited thereto, and thus, the structure can be modified in various ways.

The diode 100 and the data storage unit 200 can be connected via an electrode (not shown), and another electrode (not shown) can be formed on an upper surface of the data storage unit 200. In this case, the electrode, the data storage unit 200, and the other electrode constitute a storage node. Also, further another electrode (not shown) can be formed on a bottom surface of the p-type semiconductor layer 10. That is, the structure of FIG. 4 may be embodied in FIG. 5.

Referring to FIG. 5, a p-type semiconductor layer 10, an n-type semiconductor layer 20, a second electrode E2, a data storage layer 40, and a third electrode E3 are sequentially formed on a first electrode E1. The data storage layer 40 is equivalent to the data storage unit 200 of FIG. 4, and the second electrode E2, the data storage layer 40, and the third electrode E3 constitute a storage node.

One of the second and third electrodes E2 and E3 can have a wire shape, and the other can have a dot shape pattern, however, the second and third electrodes E2 and E3 are not limited thereto, and thus, can have various shapes. For example, both of the second and third electrodes E2 and E3 can have a wire shape and can perpendicularly cross each other, or can be formed with a dot shape pattern. A data storage layer 40 can also have various shapes. For example, the data storage layer 40 of the data storage unit 200 can be formed with a wire shape, a dot shape, or a plate shape. In FIGS. 4 and 5, the n-type semiconductor layer 20 is formed on the p-type semiconductor layer 10; however, the present invention is not limited thereto, and thus, the positions of the p-type semiconductor layer 10 and the n-type semiconductor layer 20 can be reversed.

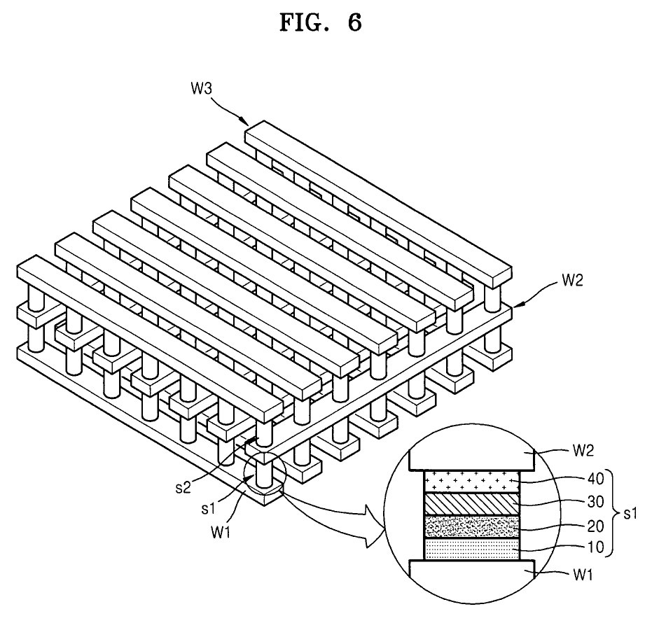

FIG. 6 is a perspective view of a multi-layer cross point resistive random access memory device comprising the structure of FIG. 5 as an unit cell structure, according to an embodiment of the present invention.

Referring to FIG. 6, a plurality of first wires W1 are formed at equal distances apart from each other on a substrate (not shown) extending in a predetermined direction. A plurality of second wires W2 are formed at equal distances apart from each other extending to perpendicularly cross the first wires W1 and the second wires W2 are a predetermined space above from the upper surfaces of the first wires W1. First structures s1 may be formed respectively at crossing points between the first wires W1 and the second wires W2. Referring to the magnified view in FIG. 6, each of the first structures s1 can include the p-type semiconductor layer 10, the n-type semiconductor layer 20, an electrode 30, and a data storage layer 40 sequentially formed on the respective first wire W1. The p-type semiconductor layer 10, the n-type semiconductor layer 20, the electrode 30, and the data storage layer 40 can have a dot shape having a similar size. The first wire W1, the electrode 30, and the second wire W2 respectively corresponds to the first, second, and third electrodes E1, E2, and E3 of the memory device of FIG. 5.

A plurality of third wires W3 can be formed a predetermined space above from the upper surfaces of the second wires W2. The third wires W3 can be formed at equal distances apart from each other, and can perpendicularly cross the second wires W2 extending in a direction perpendicularly crossing the second wires W2. A plurality of second structures s2, which respectively correspond to the first structures s1, may be formed at crossing points between the second wires W2 and the third wires W3. Other structures having the same structure as the first structures s1 and other wires can further be alternately stacked on the third wires W3. Also, in FIGS. 4 through 6, the positions of the diode and the data storage layer (or data storage unit) may be changed in various ways, for example, the positions of the diode and the data storage layer (or data storage unit) may be changed to each other. That is, the diode may be located over the date storage layer (or data storage unit).

In FIG. 6, if the data storage layer 40 is a resistance changing layer like a NiₓO_{y} layer, the structure of FIG. 6 is a multi-layer cross point resistive random access memory device. At this point, the first wires W1, the electrode 30, and the second wires W2 can be Pt layers, or other metal layers.

A diode according to an embodiment of the present invention includes a resistance changing material, thus, has a forward current density greater than a conventional diode. Thus, the diode according to an embodiment of the present invention has a forward current sufficient enough for device operation even when the diode is small in size. Accordingly, the diode according to an embodiment of the present invention is used as a switching device of a memory device of which the integration density can be increased.

While the present invention has been shown and described with reference to embodiments thereof, it should not be construed as being limited to such embodiments. One skilled in this art knows, for example, the configuration of the memory device of FIGS. 4 and 5 can include various elements. Therefore, the scope of the invention is not defined by the detailed description of the invention but by the appended claims.

What is claimed is:

1. A diode comprising a p-type semiconductor layer and an n-type semiconductor layer, wherein at least one of the p-type semiconductor layer and the n-type semiconductor layer comprises a resistance changing material whose resistance is changed according to a voltage applied to the resistance changing material.

2. The diode of claim 1, wherein the resistance changing material has a metal-insulator transition (MIT) characteristic.

3. The diode of claim 1 wherein the resistance changing material is an oxide or a sulfide.

4. The diode of claim 3, wherein the oxide comprises at least one selected from the group consisting of a vanadium oxide, a niobium oxide, and a titanium oxide.

5. The diode of claim 3, wherein the sulfide is a vanadium sulfide.

6. A memory device comprising: a diode; and a storage node connected to the diode, wherein the diode comprises a p-type semiconductor layer and an n-type semiconductor layer contacted with the p-type semiconductor layer, and at least one of the p-type semiconductor layer and the n-type semiconductor layer comprises a resistance changing material whose resistance is changed according to a voltage applied to the resistance changing material.

7. The memory device of claim 6, wherein the resistance changing material has a metal-insulator transition (MIT) characteristic.

8. The memory device of claim 6, wherein the resistance changing material is an oxide or a sulfide.

9. The memory device of claim 8, wherein the oxide comprises at least one selected from the group consisting of a vanadium oxide, a niobium oxide, and a titanium oxide.

10. The memory device of claim 8, wherein the sulfide is a vanadium sulfide.

11. The memory device of claim 6, wherein the storage node comprises a data storage layer formed of one of a resistance changing layer, a phase changing layer, a ferroelectric layer, and a magnetic layer.

12. The memory device of claim 6, wherein the storage node comprises a stack in which a lower electrode, a data storage layer and an upper electrode are sequentially stacked.

13. The memory device of claim 12, wherein the data storage layer is a resistance changing layer, and the memory device is a multi-layer cross point resistive random access memory device having a 1D(diode)-1R(resistance) cell structure.
